(19) United States
(12) Patent Application Publication
(10) Pub. No.: US 2005/0011443 A1
(43) Pub. Date: Jan. 20, 2005

(54) Organic thin film manufacturing method and manufacturing apparatus

(76) Inventors: Noriyuki Matsukaze, Nagano (JP); Hiroshi Kimura, Nagano (JP)

Correspondence Address: ROSSI & ASSOCIATES, P.O. BOX 826, ASHBURN, VA, 20146-0826, US

(21) Appl. No.: 10/788,975

(22) Filed: Feb. 27, 2004

(30) Foreign Application Priority Data
Jul. 17, 2003 (JP) JP 2003-276262

(51) Int. Cl. C23C 16/00

(52) U.S. Cl. 118/715; 427/255.6; 427/64

(57) ABSTRACT

An organic thin film manufacturing method and manufacturing apparatus is disclosed in which control of the heating method of the organic material can be carried out simply, temperature control of the organic material to be subjected to vapor deposition is easy, and the reproducibility and stability of the film thickness of the organic thin film obtained are excellent. According to the organic thin film manufacturing method an organic material is fed in a vapor state into a vapor deposition apparatus positioned in a vacuum chamber from a material introducing part positioned outside the vapor deposition apparatus to form a thin film of the organic material on at least one substrate disposed inside the vapor deposition apparatus. The material introducing part has a structure such that the pressure inside can be set independently of that inside the vapor deposition apparatus, and it also has an exhauster independent to that of the vapor deposition apparatus.

### BACKGROUND OF THE INVENTION

The present invention relates to an organic thin film manufacturing method and manufacturing apparatus. More specifically, the present invention relates to an organic thin film manufacturing method and manufacturing apparatus useful in the manufacture of organic EL devices.

In recent years, there have been rapid advances in increasing the speed of, and expanding the range of application of, information communication. High-detail display devices having low power consumption and fast response that are able to answer to the requirements on display devices with regard to portability, displaying moving pictures and so on have been devised. Since the announcement by C. W. Tang of Eastman Kodak in 1987 of a high-efficiency organic EL device (hereinafter referred to as “organic EL devices”) with a two-layer laminated structure (C. W. Tang and S. A. Van Slyke, Appl. Phys. Lett., 51, 913 (1987), various organic EL devices have been developed, and some have been put to practical use.

A method in which vapor deposition is carried out with heating has been used as the method of forming the organic compound thin films used as the light-emitting layer (hereinafter referred to as the “organic EL layer”) of an organic EL device. In this method, generally an indirect heating method is used in which a material for the thin film is housed in a vessel such as a boat or a crucible, and heating is carried out from the outside using a heater or the like. When forming an organic EL layer, it is desirable for the fluctuation in the film thickness to be within ±5% of a central value over the area of film formation. In response to this demand, improvements in large-area film formation technology have been made by using a method in which an evaporation source close to a point evaporation source or an evaporation source called a line source is used.

In order to reduce the cost of organic EL devices, it is considered to be indispensable to improve the efficiency of utilization of the organic EL layer materials. According to the current state of the art, if a point evaporation source is used then most of the vapor stream from the material attaches to the side walls of the apparatus, and very little is deposited onto the substrate on which the film is being formed. Thus, the efficiency of utilization of the material is very low. A method has thus been developed in which a line-shaped evaporation source called a line source is used, and the distance between the substrate on which the film is being formed and the evaporation source is reduced, so that there is little fluctuation in the film thickness in the longitudinal direction. This method is excellent in terms of the efficiency of utilization of the material and the ability to increase the area over which the film is formed (Japanese Patent Application Laid-open No. 2003-7464). FIG. 5 is a schematic view of a conventional vapor deposition apparatus that uses a line source. The apparatus has, inside vacuum chamber 50 that is communicated to exhauster 53, line source 51 containing heating boat 59 in which organic material 56 is housed. A substrate is disposed facing line source 51. Heating boat 59 has a heater built therein, and is connected to heater power source 54. Organic material 56 is evaporated by heating using the heater to become vapor stream 55, and hence is deposited on the surface of the substrate. The deposition of the organic material on the surface of the substrate may be monitored by film thickness measuring instrument 58 connected to film thickness measuring sensor 57. Moreover, attachment-preventing plate 52 for preventing deposition of the organic material on the side walls may also be provided.

With most evaporation sources of the line source or point evaporation source type, a method is used in which the material is filled into a heating boat, a crucible or the like or onto the base thereof. Some organic materials to be subjected to the vapor deposition are materials that sublime, while others are materials that evaporate after melting. In the case of a subliming material in particular, that part of the material in contact with the heated walls evaporates preferentially, and hence fluctuations arise in film thickness. In order to address this problem, a method has been proposed in which the vapor deposition is carried out while vibrating the evaporation source itself. Recently, an organic material vapor deposition method has been proposed in which the organic material is housed in a crucible and mixed with a powder or pulverized material of a ceramic, a metal or the like, and the crucible is heated (see Japanese Patent Application Laid-open No. 2001-323367). According to this method, the transmission of heat within the vessel can be improved, and hence improvements are realized with regard to the vapor deposition rate dropping or the sublimation efficiency dropping, regardless of the amount consumed of the material.

A method and apparatus for forming a thin film of an organic material smoothly and uniformly using a low-pressure organic vapor deposition or low-pressure organic molecular beam vapor deposition method have been proposed (see Published Japanese Translation of PCT Application No. 2001-523768). In this method the organic molecules to be subjected to vapor deposition are carried to the substrate using a carrier gas from an independent evaporation source, but there is no disclosure regarding the evaporation source and the film formation chamber having independent exhaust systems.

When a conventional type line source or point evaporation source type evaporation source is used, it is necessary to open the vacuum chamber every time the organic material being subjected to the vapor deposition is replenished, and even if the vacuum is not released, it is necessary to carry out pretreatment in which the material is heated immediately after the replenishing to drive out gases and moisture that have got into the material during storage. Furthermore, since the optimum heating conditions differ between materials that sublime and materials that evaporate after melting, there is a risk of the control of the material heating method becoming complicated.

In addition, the various organic materials used in an organic EL device each have their own temperature-vapor pressure characteristic. Generally, in view of the temperature-vapor pressure characteristic of a subliming material, the temperature range for obtaining a prescribed vapor stream is very narrow, i.e. there is high sensitivity to temperature. Temperature control is thus very important to vapor-depositing such an organic material uniformly over a large area. However, the larger the evaporation source, the larger the thermal capacity, and hence a long time is required for soaking, and temperature control becomes very difficult. Moreover, as the size of evaporation source is increased, the number of things that need to be considered with regard to the method of loading the material into heating boat 59 increases. For example, if a large amount of the material is consumed during mass production, then the surface of the evaporating material will drop down within the evaporation source, which may result in changes in the film thickness and the vapor deposition rate.

To minimize fluctuation in the film thickness in the longitudinal direction when using line source 51 as shown in FIG. 5, it is necessary to make the loading of the material into heating boat 59 uniform. It is thought that the reproducibility and stability of the film thickness will depend on the loading method.

### SUMMARY OF THE INVENTION

It is therefore an object of the present invention to provide a line source for which the various problems described above that arise during mass production are resolved, and vapor deposition over a large area is possible.

In accordance with these and other objects, an organic thin film manufacturing method according to a first embodiment of the present invention comprises feeding an organic material in a vapor state into a line source that is positioned in a vacuum chamber where deposition occurs, wherein the organic material in a vapor state is fed from a material introducing part that is positioned outside said vacuum chamber where deposition occurs, and forming a thin film of said organic material on at least one substrate disposed inside the vacuum chamber.

According to a second embodiment of the present invention an organic thin film manufacturing apparatus is provided. The apparatus is a vapor deposition apparatus comprising a line source positioned in a vacuum chamber where deposition occurs, and a material introducing part positioned outside of the vacuum chamber, in which pressure can be set independently of the pressure in the vacuum chamber, said material introducing part being connected to an exhauster that is independent to that of said vacuum chamber, wherein a vapor-state organic material is fed into said line source from the material introducing part, to form a thin film of the organic material on at least one substrate disposed inside the vacuum chamber. This manufacturing apparatus is useful as an apparatus for manufacturing the organic EL layer of organic EL devices.

According to a third embodiment of the present invention an organic EL device manufacturing method comprises forming a first electrode on at least one substrate, forming an organic EL layer on said first electrode by feeding an organic material in a vapor state from a material introducing part positioned outside a vacuum chamber where deposition occurs into a line source in the vacuum chamber where deposition occurs, wherein the pressure in the material introducing part is set independently from that of the vacuum chamber where deposition occurs and wherein the material introducing part is exhausted through an exhauster that is independent of the vacuum chamber where deposition occurs, and forming a second electrode on said organic EL layer.

An organic EL device manufacturing apparatus according to a fourth embodiment of the present invention comprises means for forming a first electrode, means for forming an organic EL layer, and means for forming a second electrode; wherein the means for forming an organic EL layer comprises a vapor deposition apparatus that has a line source positioned in a vacuum chamber where deposition occurs, and a material introducing part that is positioned outside the vacuum chamber of the vapor deposition apparatus, wherein the material introducing part and the vacuum chamber comprise separate means for setting the pressure in each of them independently and wherein the material introducing part is exhausted through an exhauster that is independent of the vacuum chamber where deposition occurs, wherein forming of the organic EL layer comprises feeding an organic material in a vapor state from the material introducing part into the line source to form the organic EL layer on at least one substrate disposed inside the vacuum chamber of said vapor deposition apparatus.

In the first to fourth embodiments described above, the material introducing part may have a crucible for holding the organic material, crucible fixing means for holding the crucible, and heating means for heating the crucible, with the organic material being vaporized by heating the crucible using the heating means. Furthermore, there may be a blocking plate for dispersing the vapor-state organic material that has been fed into the vacuum chamber, with the blocking plate being temperature-regulated so as to prevent attachment of the organic material onto the blocking plate.

### BRIEF DESCRIPTION OF THE DRAWINGS

FIG. 1 is a schematic sectional view showing a vapor deposition apparatus of the present invention.

FIG. 2 is a schematic sectional view showing a material introducing part of the vapor deposition apparatus of the present invention.

FIG. 3 is a schematic top view showing an example of a blocking plate of the vapor deposition apparatus of the present invention.

FIG. 4 is a schematic top view showing an example of a gas distributing pipe of the vapor deposition apparatus of the present invention.

FIG. 5 is a schematic sectional view showing an example of a vapor deposition apparatus using a line source according to prior art.

### DETAILED DESCRIPTION OF PREFERRED EMBODIMENTS

There are several advantages with an arrangement as presently disclosed. Because the material introducing part is independent, and the filling of the material is carried out outside the apparatus, it is not necessary to open the vacuum chamber to the atmosphere. Furthermore, because the material introducing part is independent, and the organic material is fed in as a vapor, the line source can be designed with no consideration being given to whether the organic material sublimes or melts. In addition, because the material is fed in as a vapor, it is not necessary to give consideration to the effects of the evaporation plane of the material, and even if the apparatus is used many times during mass production, there is little fluctuation in the film thickness or the film formation rate, and control is easy.

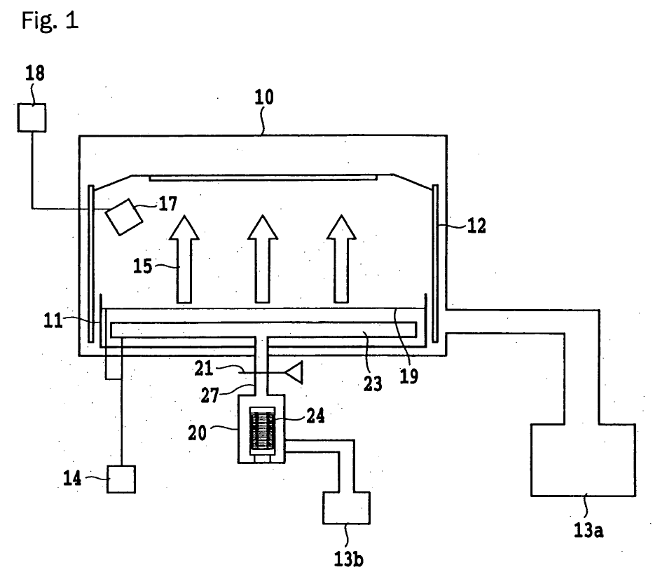

FIG. 1 is an example of an organic thin film manufacturing apparatus of the present invention. In the apparatus of the present invention, vacuum chamber 10 and material introducing part 20 are separated from one another by valve 21 provided in joint part 27, and hence form independent vacuum systems. Vacuum chamber 10 and material introducing part 20 are thus communicated respectively to independent exhausters 13a and 13b. Vacuum chamber 10 contains line source 11, and a substrate disposed so as to face line source 11. It is also possible to provide a substrate holder (not shown) that is able to hold a plurality of substrates in vacuum chamber 10, and thus carry out film formation on a plurality of substrates simultaneously. Line source 11 contains gas distributing pipe 23 that communicates with material introducing part 20 via joint part 27, and blocking plate 19 that is positioned between gas distributing pipe 23 and the substrate. Gas distributing pipe 23 and blocking plate 19 each contain heating means (not shown) for preventing attachment of the organic material, and these heating means are connected to heater power source 14. Film thickness measuring sensor 17 may be provided in vacuum chamber 10, with film thickness measuring sensor 17 being connected to film thickness measuring instrument 18, to check film thickness of the organic thin film on the substrate while it is being formed. Furthermore, attachment-preventing plate 12 may be provided on the side walls inside vacuum chamber 10. It is preferable to further provide heating means (not shown) in attachment-preventing plate 12, to prevent attachment of the organic material thereon.

With line source 11 of the present invention, the organic material is not filled into a crucible provided at the bottom of the line source. Instead the organic material is fed in a vapor state into gas distributing pipe 23 inside line source 11 from material introducing part 20, which is provided below line source 11 outside vacuum chamber 10, via joint part 27. Line source 11 has a length greater than that of the region of the substrate over which film formation is to be carried out. The desired vapor deposition can be performed by passing the substrate over line source 11, or by passing line source 11 under the substrate. Blocking plate 19 provided inside line source 11 has a large number of holes formed therein so that the vapor stream from below becomes uniform within the source. It is preferable to provide heating means (not shown) such as a heater in line source 11, to heat line source 11 and prevent deposition of the vapor-state organic material.

Blocking plate 19 is a structure for distributing the vapor of the organic material as vapor stream 15 uniformly over the whole of the substrate positioned above. The vapor is fed from gas distributing pipe 23 provided beneath blocking plate 19. Blocking plate 19 should be a plate, structure or the like able to block and distribute the vapor. There are no particular limitations on its shape and size, and any suitable shape and size may be adopted as required. FIG. 3 shows a top view of an example of blocking plate 19 that can be used in the present invention. With the structure of FIG. 3, there are a large number of stream-regulating holes 31 distributed over the whole of blocking plate 19. The shape, size and distribution of stream-regulating holes 31 can be set as appropriate. There are no particular limitations on the material of blocking plate 19, although this material must be one that will not react with or bind to the organic material that is used as the raw material. Examples of suitable materials include a metal such as Cu, Ta or Mo, an alloy such as SUS, or a ceramic such as alumina, zirconia or aluminum nitride. A material having a good thermal conductivity such as Cu or Mo is preferable. Furthermore, it is preferable to provide heating means (not shown) such as a heater in the blocking plate 19, and to connect this heating means to heater power source 14, to heat blocking plate 19 and prevent deposition of the vapor-state organic material.

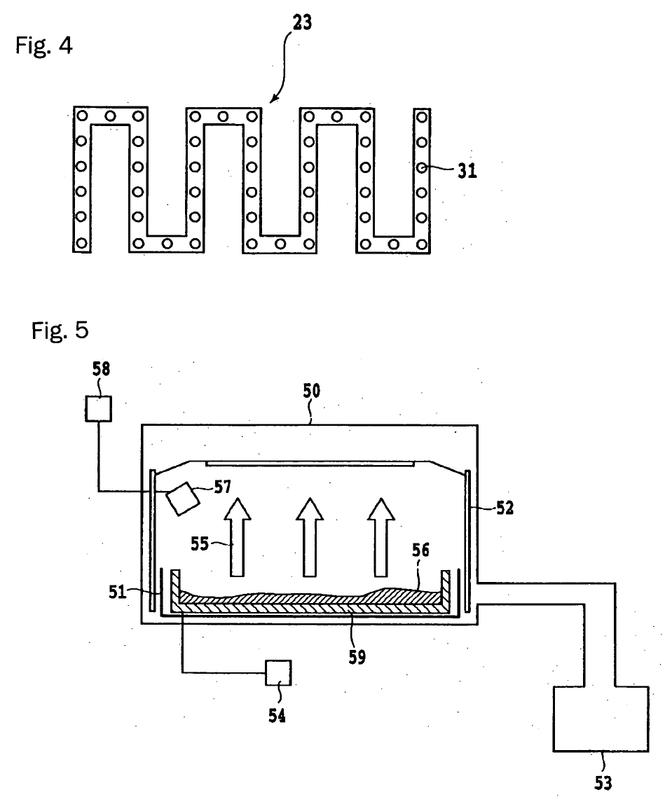

Gas distributing pipe 23 is connected to the joint part 27, and is a structure for distributing the vapor-state organic material fed in via joint part 27 uniformly throughout the whole of line source 11. Gas distributing pipe 23 should be a structure such as a pipe able to distribute a vapor, for example. There are no particular limitations on the shape and size of gas distributing pipe 23, with it being possible to adopt a suitable shape and size as required. FIG. 4 shows a top view of an example of gas distributing pipe 23 that can be used in the present invention. With the structure of FIG. 4, gas distributing pipe 23 has a plurality of right-angled parts, and has a large number of stream-regulating holes 31 along the whole of its length. The shape, size and distribution of stream-regulating holes 31 can be set as appropriate. Moreover, there are no particular limitations on the material of gas distributing pipe 23, although the material must be one that will not react with or bind to the organic material that is used as the raw material. Examples of suitable materials include a metal such as Cu, Ta or Mo, an alloy such as SUS, or a ceramic such as alumina, zirconia or aluminum nitride. A material having a good thermal conductivity such as Cu or Mo is preferable. Preferably, a heating means (not shown) is provided, such as a heater in gas distributing pipe 23. The heating means is connected to heater power source 14, to heat gas distributing pipe 23 and prevent deposition of the vapor-state organic material.

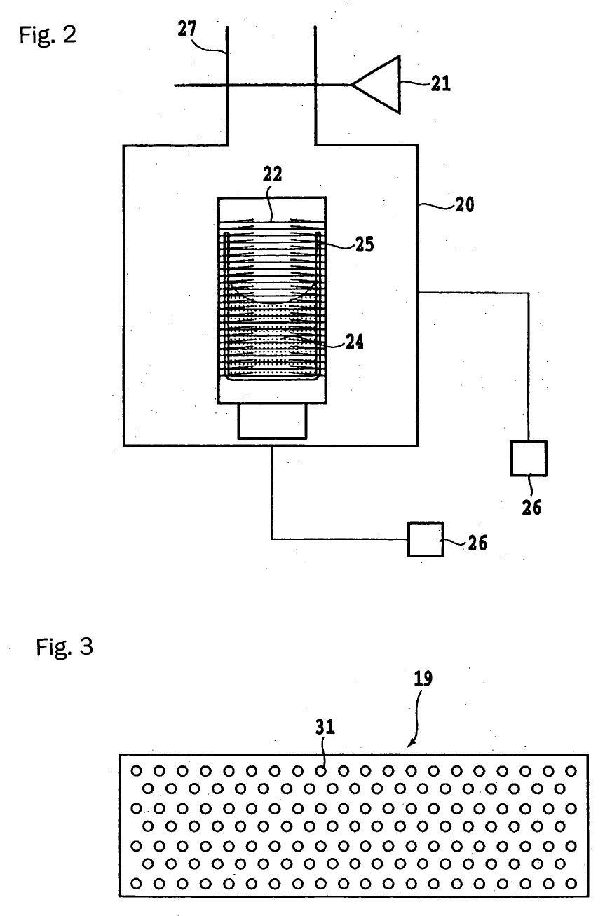

FIG. 2 is a schematic sectional view showing an example of material introducing part 20 used in the apparatus of the present invention. Material introducing part 20 has crucible 25 housing organic material 24, with crucible 25 being held by freely chosen fixing means, preferably so as to directly face joint part 27. Furthermore, heating means such as heater 22 that is connected to heater power source 26 is provided around crucible 25, and organic material 24 in crucible 25 is sublimed or else melted and then evaporated by the heating means to turn the organic material into a vapor, which is introduced into vacuum chamber 10. Moreover, a heater (not shown) may also be provided on the side walls of material introducing part 20, with this heater being connected to heater power source 26, to heat the side walls and prevent attachment of the vapor-state organic material thereon.

Alternatively, it is possible to adopt a form in which a gas introducing port (not shown) is further provided in material introducing part 20, and an inert gas such as N₂ or Ar is introduced into material introducing part 20 as a carrier gas, whereby the vapor-state organic material evaporated in crucible 25 is introduced into vacuum chamber 10.

With the apparatus of the present invention, by closing valve 21 provided in joint part 27, it is possible to change the pressure in material introducing part 20 independently of that in vacuum chamber 10. That is, it is possible to fill organic material 24 into crucible 25 with only material introducing part 20 open to atmospheric pressure.

An organic thin film manufacturing method of the present invention comprises heating and thus evaporating the organic material housed in crucible 25 in material introducing part 20, introducing the organic material in an evaporated vapor-state into gas distributing pipe 23 in line source 11 via joint part 27 and distributing the vapor-state organic material through line source 11, further introducing the vapor-state organic material into vacuum chamber 10 via blocking plate 19, and finally depositing the organic material onto the substrate on which film formation is to be carried out.

In this way, the organic material that has been vaporized in material introducing part 20 outside vacuum chamber 10 can be introduced into vacuum chamber 10, i.e., into line source 11, and hence line source 11 can be designed with no consideration being given to whether organic material 24 is a subliming material or a material that evaporates after melting. Because the organic material is fed into vacuum chamber 10 in a vapor state, it is not necessary to give consideration to the effects of changes in the evaporation plane of the material when designing line source 11, and even if the apparatus is used many times during mass production, there will be little fluctuation in the film thickness distribution or the film formation rate, and control during film formation is therefore simple. Moreover, refilling of the organic material after the organic material has been consumed through evaporation can be performed by opening only material introducing part 20 to the atmosphere, i.e., without exposing the whole of vacuum chamber 10 to the atmosphere. In addition, pretreatment involving heating to drive out gases and moisture contained in the organic material can be carried out with valve 21 closed. With the method of the present invention, the pretreatment can thus be carried out in a smaller space, and hence loss of the material during this stage can be minimized.

There are no particular limitations on the organic material used as the raw material. As long as this organic material is a material from which a film can be formed using the vapor phase deposition method, it is possible to use any of various organic materials. For example, the following can be used as the organic material in the present invention: a chain polymer such as polyacetylene or a poly-yne; an electronically conjugated organic semiconductor material such as molecular crystals of a metal chelate compound such as copper phthalocyanine, or a polyacene such as anthracene; a charge transfer complex constituted from a compound that acts as a donor such as anthracene, a diethylamine, p-phenylenediamine, tetramethyl-p-phenylendiamine (TMPD) or tetrathiofulvalene (TTF), and a compound that acts as an acceptor such as tetracyanoquinodimethane (TCNQ), tetracyanoethylene (TCNE) or p-chloranil; a colorant material; a fluorescent material; a liquid crystal material, etc.

When forming a film on the substrate, it is preferable to set the pressure in vacuum chamber 10 and material introducing part 20 to a pressure in a range of 10 Pa to 10⁻⁷ Pa, and then set the temperature of the side walls of material introducing part 20, joint part 27, gas distributing pipe 23, blocking plate 19 and attachment-preventing plate 12 to a temperature higher than the set temperature of vacuum chamber 10, to prevent attachment and recrystallization of the organic material on these parts. Furthermore, the side walls of material introducing part 20, joint part 27, gas distributing pipe 23, blocking plate 19 and attachment-preventing plate 12 are each heated by an independent heater, so that the optimum temperature for each of these parts can be set separately, and the time taken for each of these parts to reach the prescribed temperature can be shortened.

It is preferable to suitably control the temperature distributions of gas distributing pipe 23 and blocking plate 19, which affect the film thickness distribution of the organic thin film formed by depositing the organic material. The whole of each of gas distributing pipe 23 and blocking plate 19 may be set to a uniform temperature of 380 to 400° C. Alternatively, gas distributing pipe 23 and blocking plate 19 may each have a set of a plurality of independently controlled heaters, with a suitable temperature distribution being attained by separately controlling each of the plurality of heaters.

Next, valve 21 is opened, and crucible 25 is heated to about 150 to 500° C., preferably about 200 to 400° C., thus evaporating organic material 24. When a conventional line source is used the amount of the organic material charged is large, and hence the thermal capacity of the line source as a whole (in particular inside the heating boat) is large. Thus the time required for the line source to reach and stabilize at the prescribed temperature has been long. However, with the method of the present invention, recharging of the organic material is easy, and attachment of the organic material on parts other than the substrate can be prevented. As a result, the amount of the organic material charged in for use in one film formation can be reduced, so that the thermal capacity can be reduced, and the prescribed temperature can be reached in a relatively short time.

The organic thin film manufacturing method and manufacturing apparatus described above can be used in the manufacture of an organic EL device. Such an organic EL device has a structure comprising at least a first electrode, an organic EL layer and second electrode on a supporting substrate.

A variety of supporting substrates can be used. These include, for example, an insulating substrate made of glass, plastic or the like, a substrate obtained by forming a thin insulating film on a semiconductive or conductive substrate, a flexible film made from a polyolefin, an acrylic resin, a polyester resin, a polyimide resin or the like.

The first electrode and the second electrode can each be used as either an anode that injects holes into the organic EL layer or a cathode that injects electrons into the organic EL layer. For efficient hole injection, the anode preferably is formed using a material having a high work function such as a transparent electrically conductive metal oxide such as ITO (indium tin oxide) or IZO (indium zinc oxide). If a reflective anode is desired, a layered structure between such a transparent electrically conductive metal oxide and a reflective metal or alloy, e.g., a metal such as Al, Ag, Mo or W or an alloy thereof, an amorphous metal or alloy such as NiP, NiB, CrP or CrB, or a microcrystalline alloy such as NiAl, can be used for the anode. If necessary, the surface of the transparent electrically conductive metal oxide may be treated using UV, a plasma or the like, to improve the ability to inject holes into the organic EL layer. For the cathode, a material having a low work function such as an electron-injecting metal such as an alkali metal, an alkaline earth metal or aluminum, or an alloy thereof is preferable. To obtain good film formation ability and low resistivity, it is preferable to use an aluminum alloy, particularly an alloy with an alkali metal or an alkaline earth metal, or an AgMg alloy or the like. Alternatively, if a transparent cathode is desired, a laminate of an ultra-thin film, having a thickness not more than about 10 nm, of an electron-injecting metal or an alloy thereof as described above and a transparent electrically conductive oxide can be used for the cathode. The first electrode and the second electrode can be formed using a method known in the technical field in question such as vapor deposition, sputtering, CVD or laser ablation.

To produce an organic EL device in which light-emitting parts can be controlled independently of one another are arranged in a matrix shape, a passive matrix driving type device may be formed in which the first electrode and second electrode 50 are each formed from a plurality of partial electrodes in a line pattern, with the partial electrodes of the first electrode and the partial electrodes of the second electrode running in orthogonal directions. Points at which partial electrodes intersect one another emit light when a voltage is applied. Alternatively, a so-called active matrix driving type device may be formed in which switching devices (TFTs, etc.) are formed on the substrate in one-to-one correspondence with the light-emitting parts, and are connected to the first electrode, which is constituted from a plurality of partial electrodes that are made to be in one-to-one correspondence with the switching devices. This is combined with the second electrode which is formed integrally with the organic EL layer on the organic EL layer.

With the organic EL device of the present invention, light may be extracted from the substrate side (the first electrode side), or from the second electrode side. The direction from which the fight is extracted can be controlled by making one of the first electrode and the second electrode reflective, and making the other transparent.

The organic EL layer is a layer that receives injected holes and electrons, and emits light from the near ultraviolet region to visible region, preferably light in the blue to blue/green region. An organic EL layer that emits white light may also be used. When forming the organic EL device of the present invention, it is preferable to form each of the layers constituting the organic EL layer using the manufacturing method and manufacturing apparatus of the present invention. The organic EL layer has a structure comprising at least an organic light-emitting layer. If necessary a hole injection layer, a hole transport layer, an electron transport layer, and/or an electron injection layer are interposed. Specifically, an organic EL layer having a layer structure such as the following is adopted.
(1) Organic light-emitting layer
(2) Hole injection layer/organic light-emitting layer
(3) Organic light-emitting layer/electron injection layer
(4) Hole injection layer/organic light-emitting layer/electron injection layer
(5) Hole injection layer/hole transport layer/organic light-emitting layer/electron injection layer
(6) Hole injection layer/hole transport layer/organic light-emitting layer/electron transport layer/electron injection layer

In the above, the first electrode is connected to the organic light-emitting layer or the hole injection layer, and the second electrode is connected to the organic light-emitting layer or the electron injection layer.

Commercially-available materials are used as the materials of the above-mentioned layers. To obtain luminescence from blue to blue/green in color, for example, a fluorescent whitening agent of benzothiazole type, benzimidazole type, benzoxazole type or the like, a metal chelated oxonium compound, a styrylbenzene type compound, an aromatic dimethylidene type compound, or the like preferably is used in the organic light-emitting layer. Alternatively, an organic light-emitting layer that emits light in any of various wavelength regions including white light may be formed by adding a dopant to a host compound. As the host compound, a distyrylarylene type compound, N,N′-ditolyl-N,N′-diphenyl-biphenylamine (TPD), aluminum tris-(8-quinolinolate) (Alq₃), or the like can be used. As the dopant, perylene (blue/purple), Coumarin 6 (blue), a quinacridone compound (blue/green to green), rubrene (yellow), 4-dicyanomethylene-2-(p-dimethylaminostyryl)-6-methyl-4H-pyran (DCM, red), a platinum octaethylporphyrin complex (PtOEP, red), or the like can be used.

As the electron injection layer, a thin film having a thickness not more than about 10 nm of an electron-injecting material such as an alkali metal, an alkaline earth metal, or an alloy containing an alkali metal or an alkaline earth metal, or an alkali metal fluoride may be used. Alternatively, an aluminum quinolinol complex doped with an alkali metal or an alkaline earth metal may be used. As the material of the electron transport layer, an oxadiazole derivative such as 2-(4-biphenyl)-5-(p-t-butylphenyl)-1,3,4-oxadiazole (PBD), a triazole derivative, a triazine derivative, a phenylquinoxaline, an aluminum quinolinol complex, e.g., Alq₃, or the like can be used.

A commercially-available material can be used as the material of the hole transport layer. Exemplary of such materials are a triarylamine type material such as TPD, N,N′-bis(1-naphthyl)-N,N′-diphenyl-biphenylamine (α-NPD) or 4,4′,4″-tris(N-3-tolyl-N-phenylamino)triphenylamine (m-MTDATA). As the material of the hole injection layer, a phthalocyanine such as copper phthalocyanine, an indanthrene compound, or the like can be used.

An organic EL device that emits light of desired hues also may be formed by further providing color filter layers and/or color-converting layers on the organic EL device described above. Color filter layers are layers that transmit only light in a specific wavelength region out of the light emitted from the organic EL layer. Color-converting layers are layers that carry out so-called wavelength distribution conversion, absorbing a specific wavelength region component of the light emitted from the organic EL layer and emitting light in a different wavelength region. For example, red color-converting layers that absorb a component from blue to blue/green in color and emit red light may be provided. The color purity of the emitted light may also be improved by using a combination of a color-converting layer and a color filter layer. Furthermore, in the case of using an organic EL device having a plurality of independently controlled light-emitting parts, by combining a plurality of types of color filter layers and/or color-converting layers, a multi-color display can be formed. The color-converting layers and color filter layers can be formed from any chosen material known in the technical field in question.

Following is a more concrete description of the present invention through examples; however, it goes without saying that the present invention is not limited by these examples, with it being possible to make various changes within a scope such that the gist of the present invention is not deviated from.

### EXAMPLE 1

Using the film manufacturing apparatus shown in FIG. 1, a confirmatory test was carried out into the stability of the film formation rate. Glass substrates each having dimensions of 50 mm×50 mm were arranged in 15 rows by 3 columns in a substrate holder having a mounting region of dimensions 770 mm×150 mm inside vacuum chamber 10, which had an internal volume of 0.2 m³. Blocking plate 19 had dimensions of 800 mm×200 mm, and had circular stream-regulating holes of diameter 3 mm distributed uniformly over the whole thereof, with the aperture ratio (total area of stream-regulating holes/total area of blocking plate) being 0.5%. The distance between blocking plate 19 and the substrates was made to be 150 mm. Moreover, a crucible 25 having a bore diameter of 50 mm and a depth of 100 mm was provided in the material introducing part 20, which had an internal volume of 0.05 m³, and 100 g of aluminum tris-(8-quinolinolate) (Alq₃) was charged into the crucible 25. Alq₃ is a material that is commonly used as an electron-transporting material in organic EL devices, and is known to sublime. Vacuum chamber 10 and material introducing part 20 were connected together by joint part 27, which was an SUS pipe of internal diameter 20 mm, and the tip of this pipe was connected to gas distributing pipe 23, which had an internal diameter of 4 mm and had circular stream-regulating holes of diameter 2 mm distributed uniformly thereover.

Using the above apparatus, the target film formation rate was set to 10 nm/sec, and a verificatory investigation was carried out into the controllability and the temperature rising process. Regarding the heaters for the blocking plate, the joint part, and the side walls of the material introducing part, the target temperature was set to 400° C. The pressure in the vacuum chamber 10 and material introducing part 20 was reduced to 10⁻⁵ Pa, and then the power sources for all of the heaters were turned on simultaneously.

After the power sources had been turned on and the temperature of each of the parts had stabilized, the power source was turned on for the heater of the crucible, which was set to a target temperature of 320° C. The Alq₃ was thus heated, and 2 hours was required for the rate of the film formation onto the substrates to reach 10 nm/sec. During the experimental sequence, approximately 8 g of the organic material in the crucible was lost.

### COMPARATIVE EXAMPLE 1

Using the conventional film manufacturing apparatus shown in FIG. 5, a confirmatory test was carried out into the controllability, the temperature rising process, and the stability of the film formation rate as in Example 1. Glass substrates each having dimensions of 50 mm×50 mm were arranged in 15 rows by 3 columns in a substrate holder having a mounting region of dimensions 770 mm×150 mm inside vacuum chamber 50, which had an internal volume of 0.2 m³. Resistive heating boat 59, which had an opening part of dimensions 850 mm×35 mm and a depth of 50 mm, was positioned 150 mm from the surface of the glass substrates, and 100 g of Alq₃ was charged therein.

Next, the pressure in vacuum chamber 50 was reduced to 10⁻⁵ Pa, and the power source was turned on for the heater of attachment-preventing plate 52, which was set to a target temperature of 400° C.

After the power source had been turned on and the temperature of each of the parts had stabilized, the power source was turned on for the heater of the resistive heating boat, which was set to a target temperature of 320° C., thus commencing film formation. The Alq₃ was thus heated, and approximately 5 hours was required for the rate of the film formation onto the substrates to reach 10 nm/sec. The amount of the Alq₃ lost from inside the boat from turning on the power source until the temperature of each of the parts stabilized was as much as approximately 20 g.

### EXAMPLE 2

Using the apparatus described in Example 1, film formation was carried out over 30 seconds such that the mean film thickness would be 300 nm, thus forming Alq₃ on the glass substrates.

After that, the film thickness of the organic thin film was measured for all of the glass substrates using a stylus type film thickness gauge. The result was that the film thickness variation index (the ratio of the thickness of the thinnest organic thin film to the thickness of the thickest organic thin film out of the 45 glass substrates) was 0.9 or more. This demonstrates that thin films of uniform thickness with little fluctuation in the film thickness can be formed according to the organic thin film manufacturing method of the present invention.

Furthermore, using the apparatus of the present invention, an investigation was carried out into the reproducibility of the film thickness upon carrying out film formation many times. Using the apparatus of Example 1, 30 seconds of Alq₃ film formation was carried out 50 times in succession, without replenishing the organic material between runs. The Alq₃ thin films obtained on the fiftieth run exhibited a mean film thickness of 296 nm, and a film thickness variation index of 0.9 or more, and hence the film thickness and the uniformity thereof were approximately the same as for the Alq₃ thin films obtained on the first run. Thus, even when film formation is carried out repeatedly such that the organic material in the crucible is consumed, high film thickness reproducibility is obtained according to the method of the present invention.

### COMPARATIVE EXAMPLE 2

Using the apparatus described in Comparative Example 1, film formation was carried out over 30 seconds such that the mean film thickness would be 300 nm, thus forming Alq₃ on the glass substrates. After that, the film thickness of each of the manufactured organic thin films was measured using a stylus type film thickness gauge. The result was that the film thickness variation index was not over 0.8, i.e., it was found that there were large fluctuations in the film thickness.

Upon separately providing a radiation thermometer in vacuum chamber 50, and monitoring the temperature of line source 51, it was found that fluctuations in temperature of approximately 5 to 10° C. existed along the longitudinal direction of line source 51, and that this was one factor in the large fluctuations in the film thickness. Moreover, it is thought that unevenness in the introduction of organic material 56 into line source 51 (more specifically resistive heating boat 59) also had an effect.

An investigation was also carried out into the reproducibility of the film thickness upon carrying out film formation many times. Using the apparatus of Comparative Example 1, 36 seconds of Alq₃ film formation was carried out 50 times in succession, without replenishing the organic material between the runs. The Alq₃ thin films obtained on the eleventh run exhibited a mean film thickness of 360 nm and a film thickness variation index of 0.8, i.e., a film thickness approximately the same as that for the Alq₃ thin films obtained on the first occasion could not be obtained. From this result, it can be seen that the film thickness reproducibility for the apparatus using the conventional evaporation source is poor.

### EXAMPLE 3

Using the film manufacturing apparatus of Example 1, trial manufacture of organic EL devices was carried out. Three film manufacturing apparatuses according to Example 1 were linked to a vacuum vessel for conveyance having a load lock, so that substrates could be moved between the film manufacturing apparatuses without releasing the vacuum. Glass substrates (dimensions 50 mm×50 mm) on each of which an ITO film had been formed to a thickness of 100 nm were mounted, arranged in 15 rows by 3 columns, on a substrate holder having a mounting region of dimensions 770 mm×150 mm, and the substrate holder was conveyed into the vacuum vessel for conveyance from the load lock.

Next, the substrate holder was conveyed into the first film manufacturing apparatus, and an α-NPD film of thickness 40 nm was deposited at a film formation rate of 2 nm/sec, thus forming a hole transport layer on each of the substrates. The substrate holder was then conveyed into the second film manufacturing apparatus, and an Alq₃ film of thickness 60 nm was deposited at a film formation rate of 2 nm/sec, in order to form an electron-transporting light-emitting layer on each of the substrates. Finally, the substrate holder was conveyed into the third film manufacturing apparatus, and an Ag-Mg alloy (Mg 90 mass %) film of thickness 100 nm was deposited at a film formation rate of 2 nm/sec, in order to form an electron-injecting cathode on each of the substrates, whereby organic EL devices were obtained.

A voltage of 20 V was applied to each of the 45 organic EL devices obtained, taking the ITO film as the anode and the Ag-Mg film as the cathode, and the current efficiency for the brightness was measured. The mean current efficiency for the 45 devices was 4 cd/A, and the variation in the current efficiency (the absolute value of the ratio of the maximum deviation from the mean current efficiency to the mean current efficiency) was within Δ10%.

### COMPARATIVE EXAMPLE 3

Organic EL devices were manufactured as in Example 3, except that the apparatus of Comparative Example 1 was used as the film manufacturing apparatuses.

Evaluation of the 45 devices obtained showed that the mean current efficiency was approximately the same as in Example 3. However, the variation in the current efficiency was large at Δ20%. It is thought that the fluctuation in the film thickness for the devices as described in Comparative Example 2 was a large factor in this variation arising.

As described above, according to the present invention, an organic thin film manufacturing apparatus and manufacturing method can be realized according to which: the filling of the organic material is carried out in a material introducing part that is independent to the vacuum chamber, and hence it is not necessary to open the vacuum chamber to the atmosphere during this filling; the material is fed into the vacuum chamber in a vapor state from the independent material introducing part, and hence the line source can be designed with no consideration being given to whether the material used is a subliming material or a material that evaporates after melting; it is not necessary to give consideration to the effects of changes in the evaporation plane of the material during manufacture; even if the apparatus is used many times during mass production, there is little fluctuation in the film thickness or the film formation rate; the efficiency of utilization of the organic material is high; control is easy, mass production is possible, and vapor deposition of an organic material onto large-area substrates is possible. The manufacturing apparatus and manufacturing method are particularly effective in the manufacture of large-area organic EL devices.

1. An organic thin film manufacturing method, comprising:
feeding an organic material in a vapor state into a line source that is positioned in a vacuum chamber where deposition occurs, wherein said organic material in a vapor state is fed from a material introducing part that is positioned outside said vacuum chamber where deposition occurs, and
forming a thin film of said organic material on at least one substrate disposed inside said vacuum chamber,
wherein the pressure inside said material introducing part is set independently of the pressure inside said vacuum chamber where deposition occurs, and wherein said material introducing part is exhausted through an exhauster that independent of the exhauster of said vacuum chamber.

2. The organic thin film manufacturing method according to claim 1, wherein said material introducing part comprises a crucible for holding said organic material, crucible fixing means for holding said crucible, and heating means for heating said crucible, and said organic material is vaporized by heating said crucible using said heating means.

3. The organic thin film manufacturing method according to claim 1, wherein said line source has a blocking plate for dispersing the vapor-state organic material that has been fed therein, and said blocking plate is temperature-regulated.

4. An organic thin film manufacturing apparatus, comprising:
a vapor deposition apparatus comprising a line source positioned in a vacuum chamber where deposition occurs, and
a material introducing part positioned outside of said vacuum chamber, in which pressure can be set independently of the pressure in said vacuum chamber, said material introducing part being connected to an exhauster that is independent to that of said vacuum chamber,
wherein a vapor-state organic material is fed into said line source from said material introducing part, to form a thin film of said organic material on at least one substrate disposed inside said vacuum chamber.

5. The organic thin film manufacturing apparatus according to claim 4, wherein said material introducing part comprises a crucible for holding said organic material, crucible fixing means for holding said crucible, and heating means for heating said crucible.

6. The organic thin film manufacturing apparatus according to claim 4, wherein said line source has a blocking plate for dispersing the vapor-state organic material that has been fed therein, and said blocking plate is temperature-regulated.

7. An organic EL device manufacturing method, comprising:
forming a first electrode on at least one substrate;
forming an organic EL layer on said first electrode by feeding an organic material in a vapor state from a material introducing part positioned outside a vacuum chamber where deposition occurs into a line source in said vacuum chamber where deposition occurs, wherein the pressure in said material introducing part is set independently from that of said vacuum chamber where deposition occurs and wherein said material introducing part is exhausted through an exhauster that is independent of said vacuum chamber where deposition occurs; and
forming a second electrode on said organic EL layer.

8. The organic EL device manufacturing method according to claim 7, wherein said material introducing part comprises a crucible for holding said organic material, crucible fixing means for holding said crucible, and heating means for heating said crucible, and said organic material is vaporized by heating said crucible using said heating means.

9. The organic EL device manufacturing method according to claim 7, wherein said line source has a blocking plate for dispersing the vapor-state organic material that has been fed therein, and said blocking plate is temperature-regulated.

10. An organic EL device manufacturing apparatus, comprising:
means for forming a first electrode;
means for forming an organic EL layer; and
means for forming a second electrode;
wherein said means for forming an organic EL layer comprises a vapor deposition apparatus that has a line source positioned in a vacuum chamber where deposition occurs, and a material introducing part that is positioned outside said vacuum chamber of said vapor deposition apparatus, wherein said material introducing part and said vacuum chamber comprise separate means for setting the pressure in each of them independently and wherein said material introducing part is exhausted through an exhauster that is independent of said vacuum chamber where deposition occurs,
wherein forming of said organic EL layer comprises feeding an organic material in a vapor state from said material introducing part into said line source to form said organic EL layer on at least one substrate disposed inside said vacuum chamber of said vapor deposition apparatus.

11. The organic EL device manufacturing apparatus according to claim 10, wherein said material introducing part comprises a crucible for holding said organic material, crucible fixing means for holding said crucible, and heating means for heating said crucible.

12. The organic EL device manufacturing apparatus according to claim 10, wherein said line source comprises a blocking plate for dispersing the vapor-state organic material that has been fed therein, and said blocking plate is temperature-regulated.
